(19) United States
(12) Patent Application Publication
(10) Pub. No.: US 2026/0189070 A1
(43) Pub. Date: Jul. 2, 2026

(54) WIRELESS CHARGING FOR A ROBOT END EFFECTOR

(71) Applicant: Applied Materials, Inc., Santa Clara, CA (US)

(72) Inventors: William Paul Laceky, Georgetown, TX (US); Stephen Wells, Round Rock, TX (US)

(21) Appl. No.: 19/007,829

(22) Filed: Jan. 2, 2025

(51) Int. Cl. H02J 50/10; H01L 21/687; H02J 50/80

(52) U.S. Cl. CPC H02J 50/10; H02J 50/80; H10P 72/7602

(57) ABSTRACT

A substrate processing system includes a transfer chamber and at least one process chamber coupled with the transfer chamber. The substrate processing system further includes a substrate-handling robot disposed within the transfer chamber. The substrate-handling robot includes a power receiver located proximate an end effector of the substrate-handling robot for handling a substrate. The substrate processing system further includes at least one power transmitter disposed proximate a facet between the transfer chamber and the at least one process chamber. The power transmitter is configured to wirelessly transmit power to the power receiver when the power receiver is substantially aligned with the power transmitter.

### TECHNICAL FIELD

This instant specification generally relates to a system for wireless charging for a robot end effector (e.g., a substrate-handling robot end effector). The instant disclosure relates specifically to a wireless charging system, and methods and systems related to the wireless charging system.

### BACKGROUND

Substrates are often transported throughout a processing system by substrate-handling robots. A substrate-handling robot may include one or more end effectors for gripping and/or supporting a substrate for transportation. The substrate-handling robot may transport the substrate to and/or from one of multiple substrate hand-off location (e.g., such as processing chambers, etc.) within the processing system.

### SUMMARY

In one embodiment, a substrate processing system includes a transfer chamber and at least one process chamber coupled with the transfer chamber. The substrate processing system further includes a substrate-handling robot disposed within the transfer chamber. The substrate-handling robot includes a power receiver located proximate an end effector of the substrate-handling robot for handling a substrate. The substrate processing system further includes at least one power transmitter disposed proximate a facet between the transfer chamber and the at least one process chamber. The power transmitter is configured to wirelessly transmit power to the power receiver when the power receiver is substantially aligned with the power transmitter.

In one embodiment, a robot includes one or more robot arms and an end effector coupled with a robot arm of the one or more robot arms. The end effector is configured o handle a substrate. The end effector includes an electrical load. The robot further includes a power receiver disposed the robot arm or on the end effector. The power receiver is configured to wirelessly receive power from a power transmitter when the power receiver is substantially aligned with the power transmitter. The electrical load is to be powered using the received power.

In one embodiment, an electronics processing system includes one or more chambers. The electronics processing system further includes a substrate-handling robot disposed in a chamber of the one or more chambers. The electronics processing system further includes a power transmitter disposed proximate to a transfer path of the substrate-handling robot and configured to wirelessly provide power to a power receiver of the substrate-handling robot when the power receiver is substantially aligned with the power transmitter.

### BRIEF DESCRIPTION OF THE DRAWINGS

Aspects and embodiments of the present disclosure will be understood more fully from the detailed description given below and from the accompanying drawings of various aspects and embodiments of the disclosure, which, however, should not be taken to limit the disclosure to the specific aspects or embodiments, but are for explanation and understanding only. The drawings, described below, are for illustrative purposes and are not necessarily drawn to scale.

FIG. 1 illustrates a schematic view of an example manufacturing system (e.g., a substrate processing system), in accordance with some embodiments of the present disclosure.

FIG. 2 illustrates an example schematic view of an electronic circuit, in accordance with some embodiments of the present disclosure.

FIGS. 3A-C illustrate simplified side views of systems utilizing wireless charging for a robot end effector, in accordance with some embodiments of the present disclosure.

FIG. 4 illustrates a simplified side view of a system utilizing wireless charging for a robot end effector, in accordance with some embodiments of the present disclosure.

FIG. 5 illustrates a plot of a charging profile for wireless charging of a robot end effector, in accordance with some embodiments of the present disclosure.

FIG. 6 is a flow diagram of a method for wirelessly charging a robot end effector, in accordance with some embodiments of the present disclosure.

### DETAILED DESCRIPTION

Semiconductor device manufacturing and other device manufacturing (e.g., such as for displays, photovoltaic devices, etc.) often involves tens and even hundreds of complex operations to implement raw substrate (e.g., wafer) preparation, polishing, material deposition, etching, and the like. Substrates that are delivered for processing in processing chambers can include bare substrates (e.g., silicon substrates, quartz substrates, Gallium Arsenide substrates, corundum substrates), substrates that have been preprocessed (e.g., covered with one or more films, such as carbon films), or substrates that have already undergone one or more processing operations (e.g., deposition, patterning, etching, and so on). In some embodiments, substrates are transported to and/or from a processing chamber by a substrate-handling robot. In some embodiments, the substrate-handling robot includes one or more end effectors each configured to support and transport a substrate. In some embodiments, the substrate-handling robot includes multiple end effectors to facilitate the transport of multiple substrates simultaneously.

Some robot end effectors include a device having an electrical load that is to be powered while transporting substrates. For example, and in some embodiments, an end effector can include a heater, one or more sensors, and/or an electrostatic chuck. Each of these example devices can be powered by electricity during transport of a substrate from one hand-off location to another. Electrical charge stored in an associated power storage device (e.g., battery, capacitor, etc.) may dissipate while the electrical load is activated (e.g., the electrical charge may power the electrical load, draining the stored electrical charge).

In some embodiments, an electrostatic chuck incorporated in a robot end effector is activated to provide grip on a substrate such as during transportation of the substrate from one hand-off location to another hand-off location. When a substrate is supported by an end effector, the electrostatic chuck incorporated into the end effector may be activated (e.g., energized, etc.). Activation of the electrostatic chuck generates an electrostatic force that electrostatically clamps the substrate to the end effector. Without an electrostatic chuck, if the end effector accelerates or decelerates too quickly, the substrate may slide on the end effector or otherwise become dislodged and may shift, causing inaccurate placement of the substrate at the next hand-off location, particle generation, and/or substrate damage. In some embodiments, however, when a substrate is held to the end effector by an electrostatic force (e.g., generated by the electrostatic chuck incorporated into the end effector), the end effector can more quickly accelerate and/or decelerate without dislodging or displacing the substrate. The quicker accelerations of robot end effectors using electrostatic chucks to secure substrates on the end effectors can therefore transport substrates quicker, leading to increased throughput of the entire processing system.

To power an electrical load on a robot end effector (such as a heater, a sensor, an electrostatic chuck, etc.), electricity can be delivered to the end effector at least one of several ways. For example, electricity can be delivered to the end effector by wires. However, to deliver electricity to the end effectors using wires, the wires are to be routed through the robot arms and joints, etc. It may be difficult to route wires through the robot arms and/or joints without disrupting the operation of the robot, especially if the robot is an infinite rotation type robot (e.g., can rotate an infinite number of times about a robot joint). Additionally, the wires are to be insulated against shorts and/or are to be hermetically sealed. In some embodiments, the electrical load at the robot end effector can be powered using a power storage device such as a battery or a capacitor (e.g., a super capacitor, etc.). However, batteries may not be suitable for use in vacuum environment and may be subject to damage (e.g., such as rupture, etc.). Additionally, batteries may be subject to more frequent maintenance (e.g., changing out “dead” batteries, etc.) and may add additional size and/or weight to the robot assembly. Moreover, power storage devices may quickly run out of electrical power when used to power an electrical load such as a heater or an electrostatic chuck. It may be impractical to replace batteries on robot end effectors because the processing system may be temporarily shut down for battery replacement. A system to charge a power storage device for powering an electrical load at a robot end effector may be advantageous.

Aspects and embodiments of the present disclosure address the above-described problem and shortcomings by providing a system for wirelessly charging a power storage device used to power an electrical load at a robot end effector. In some embodiments, by wirelessly providing power to the robot end effector (e.g., to a power storage device at the end effector, etc.), wires traversing the robot arms and/or extending through the robot joints can be minimized or avoided altogether. In some embodiments, power is provided wirelessly to a robot end effector by inductive charging. During operation of the robot, the end effector may pick up or drop off substrates at predefined substrate hand-off locations, such as process chambers, degassing chambers, or pedestals, etc. While placing or picking up a substrate, the end effector may be at a defined position. A power transmitter may be positioned near a first hand-off location such that the power transmitter is aligned to interact with a power receiver on the robot when the end effector is to pick up or drop off a substrate at the first hand-off location. In some embodiments, the power receiver is on the end effector but may alternatively be on a wrist or other member of the robot. The power transmitter may transmit electrical power to the receiver, such as by inductive power transfer as described herein. However, the power transmitter may alternatively transmit power by solar or optical power transfer or by RF power transfer, etc. A power storage device electrically coupled with the power receiver may be charged by the power received by the receiver. When the end effector moves away from the first hand-off location, the electrical load on the end effector (e.g., an electrostatic chuck, a heater, and/or one or more sensors, etc.) may be powered using the electricity stored in the power storage device. The end effector may move to a second hand-off location where another power transmitter may be positioned to interact with the power receiver on the robot. Power may be transferred from the transmitter to the receiver and the power storage device may be re-charged in part or in full.

Aspects and embodiments of the present disclosure may result in technological advances. For example, electrical loads at substrate-handling robot end effectors (e.g., such as electrostatic chucks, heaters, sensors, etc.) can be powered with minimal or even without using any wires and/or conductors that extend through the robot arms and/or robot joints. Additionally, power storage devices for powering the electrical loads can be efficiently re-charged without affecting the operation of the robot. For example, the power storage device can be re-charged while the robot picks or places a substrate at one or more predefined substrate hand-off locations without affecting the robot's operational efficiency. Moreover, in embodiments where the electrical load on the end effector is an electrostatic chuck, the substrate-handling robot can more quickly accelerate substrates for transportation without the substrates sliding or otherwise becoming dislodged on the end effector, which can lead to increased productivity of the robot and an increase in overall system throughput.

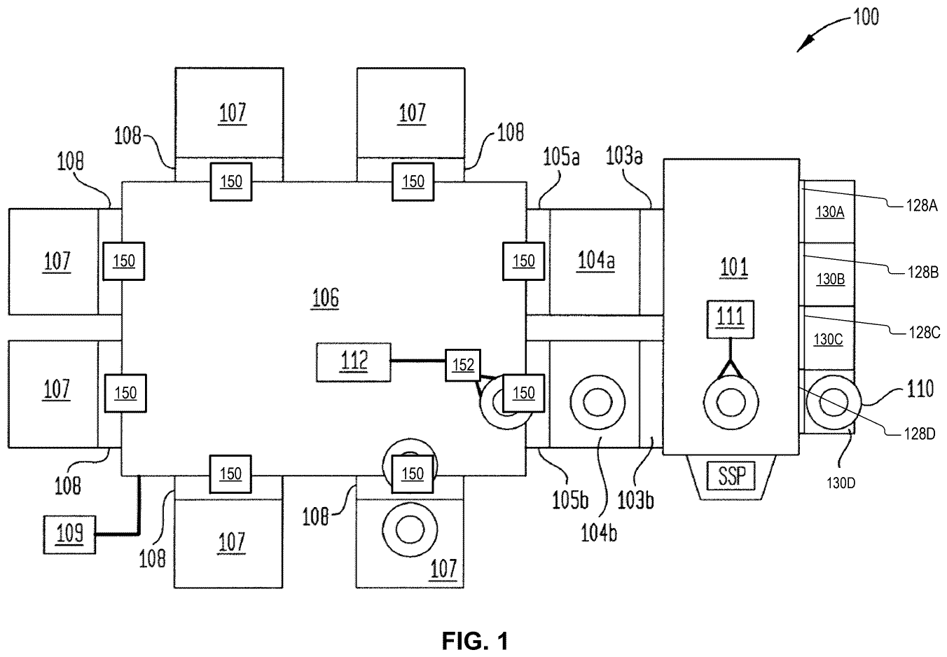

FIG. 1 illustrates a schematic view of an example manufacturing system 100 (e.g., a substrate processing system), in accordance with some embodiments of the present disclosure. The manufacturing system 100 includes a factory interface (FI) 101 and load ports 128x (e.g., load ports 128A-D). In some embodiments, the load ports 128A-D are directly mounted to (e.g., sealed against) FI 101. Enclosure systems 130x (e.g., cassette, FOUP, process kit enclosure system, or the like) are configured to removably couple (e.g., dock) to the load ports 128A-D. In some embodiments, enclosure system 130A is coupled to load port 128A, enclosure system 130B is coupled to load port 128B, enclosure system 130C is coupled to load port 128C, and enclosure system 130D is coupled to load port 128D. In some embodiments, one or more enclosure systems 130x are coupled to the load ports 128x for transferring substrates and/or other items into and out of the processing manufacturing system 100. Each of the enclosure systems 130x may seal against a respective load port 128x. In some embodiments, a first enclosure system 130A is docked to a load port 128A. Once such operation or operations are performed, the first enclosure system 130A is undocked from the load port 128A, and then a second enclosure system 130x (e.g., a FOUP containing substrate(s)) is docked to the same load port 128A. In some embodiments, an enclosure system 130x (e.g., enclosure system 130A) is a system for performing a calibration operation or a diagnostic operation.

In some embodiments, a load port 128x includes a front interface that forms an opening. The load port 128x additionally includes a horizontal surface for supporting an enclosure system 130x. Each enclosure system 130x has a front interface that forms a vertical opening. The front interface of the enclosure system 130x is sized to interface with (e.g., seal to) the front interface of the load port 128x (e.g., the vertical opening of the enclosure system 130x is approximately the same size as the vertical opening of the load port 128x). The enclosure system 130x is placed on the horizontal surface of the load port 128x and the vertical opening of the enclosure system 130x aligns with the vertical opening of the load port 128x. The front interface of the enclosure system 130x interconnects with (e.g., clamp to, be secured to, be sealed to) the front interface of the load port 128x. A bottom plate (e.g., base plate) of the enclosure system 130x has features (e.g., load features, such as recesses or receptacles, that engage with load port kinematic pin features, a load port feature for pin clearance, and/or an enclosure system docking tray latch clamping feature) that engage with the horizontal surface of the load port 128x. The same load ports 128x that are used for different types of enclosure systems 130x.

In some embodiments, the manufacturing system 100 also includes first vacuum ports 103a, 103b coupling FI 101 to respective degassing chambers 104a, 104b. Second vacuum ports 105a, 105b are coupled to respective degassing chambers 104a, 104b and disposed between the degassing chambers 104a, 104b and a transfer chamber 106 to facilitate transfer of substrates and other content 110 (e.g., substrate supports such as susceptors, etc.) into the transfer chamber 106. In some embodiments, the degassing chambers 104 are separated from the transfer chamber 106 each by a facet, into which a corresponding vacuum port 105 is incorporated. In some embodiments, a manufacturing system 100 includes and/or uses one or more degassing chambers 104 and a corresponding number of vacuum ports 103, 105 (e.g., a manufacturing system 100 includes a single degassing chamber 104, a single first vacuum port 103, and a single second vacuum port 105). The transfer chamber 106 includes a plurality of processing chambers 107 (e.g., four processing chambers 107, six processing chambers 107, etc.) disposed therearound and coupled thereto. The processing chambers 107 are coupled to the transfer chamber 106 through respective ports 108, such as slit valves or the like. In some embodiments, the processing chamber 107 are separated from the transfer chamber 106 each by a facet, into which a corresponding port 108 is incorporated. In some embodiments, FI 101 is at a higher pressure (e.g., atmospheric pressure) and the transfer chamber 106 is at a lower pressure (e.g., vacuum). Each degassing chamber 104 (e.g., load lock, pressure chamber) has a first door (e.g., first vacuum port 103) to seal the degassing chamber 104 from FI 101 and a second door (e.g., second vacuum port 105) to seal the degassing chamber 104 from the transfer chamber 106. Content is to be transferred from FI 101 into a degassing chamber 104 while the first door is open and the second door is closed, the first door is to close, the pressure in the degassing chamber 104 is to be reduced to match the transfer chamber 106, the second door is to open, and the content is to be transferred out of the degassing chamber 104. A local center finding (LCF) device is to be used to align the content in the transfer chamber 106 (e.g., before entering a processing chamber 107, after leaving the processing chamber 107).

In some embodiments, the processing chambers 107 includes or more of etch chambers, deposition chambers (including atomic layer deposition, chemical vapor deposition, physical vapor deposition, or plasma enhanced versions thereof), anneal chambers, or the like.

Factory interface 101 includes a factory interface robot 111. Factory interface robot 111 includes a robot arm, such as a selective compliance assembly robot arm (SCARA) robot. Examples of a SCARA robot include a 2 link SCARA robot, a 3 link SCARA robot, a 4 link SCARA robot, and so on. The factory interface robot 111 includes an end effector on an end of the robot arm. The end effector is configured to pick up and handle specific objects, such as wafers. Alternatively, or additionally, the end effector is configured to handle objects such as a substrate support (e.g., a susceptor), which may or may not have a wafer disposed thereon. Accordingly, in some embodiments, substrate supports and supported wafers (or other substrates) may be transferred together by the robot arm. The robot arm has one or more links or members (e.g., wrist member, upper arm member, forearm member, etc.) that are configured to be moved to move the end effector in different orientations and to different locations.

The factory interface robot 111 is configured to transfer objects (e.g., substrates, substrate supports, or combinations thereof) between enclosure systems 130x (e.g., cassettes, FOUPs) and degassing chambers 104a, 104b (or load ports). The factory interface robot 111 is taught a fixed location relative to a load port 128x using the enclosure system 130x in embodiments. The fixed location in one embodiment corresponds to a center location of an enclosure system 130A placed at a particular load port 128x, which in embodiments also corresponds to a center location of an enclosure system 130B placed at the particular load port 128x. Alternatively, the fixed location may correspond to other fixed locations within the enclosure system 130x, such as a front or back of the enclosure system 130x. The factory interface robot 111 is calibrated using the enclosure system 130x in some embodiments. The factory interface robot 111 is diagnosed using the enclosure system 130x in some embodiments.

Transfer chamber 106 includes a transfer chamber robot 112. Transfer chamber robot 112 includes a robot arm with an end effector at an end of the robot arm. The end effector is configured to handle particular objects, such as wafers. In some embodiments, the transfer chamber robot 112 is a SCARA robot, but may have fewer links and/or fewer degrees of freedom than the factory interface robot 111 in some embodiments. In some embodiments, the transfer chamber robot 112 includes one or more end effectors having an electrically powered device thereon. An electrical device on an end effector may constitute an electrical load. The electrical device incorporated into an end effector may be a heater, an electrostatic chuck, and/or one or more sensors. In some embodiments, the electrical device may be activated while the transfer chamber robot 112 transports a substrate (e.g., content 110, etc.) from one hand-off location to another hand-off location, such as from degassing chamber 104a to one of the processing chamber 107, etc., or vice versa. For example, an electrostatic chuck in an end effector may be energized and may generate an electrostatic clamping force to secure a substrate on the end effector while the substrate is transported from a processing chamber 107 to the degassing chamber 104b. A power storage device on the end effector or on the distal arm of the transfer chamber robot 112 may provide electrical power for powering the electrical device on the end effector. In some embodiments, the power storage device includes one or more capacitors, such as a super capacitor, etc. The capacitor(s) may be included in circuitry (e.g., a printed circuit, etc.) on the end effector.

The power storage device(s) on the transfer chamber robot 112 may be depleted after powering the electrical device on the robot end effector(s). In some embodiments, a power charging system wirelessly charges (e.g., re-charges) the power storage device. Multiple power transmitters 150 may be located throughout the transfer chamber 106 at or proximate a corresponding substrate hand-off location. For example, power transmitters may be proximate to the facets separating the process chambers 107 from the transfer chamber 106 and/or separating the degassing chambers 104 from the transfer chamber 106. The power transmitters 150 may be inductive power transmitters, solar, optical, or radio frequency (RF) power transmitters. Each of the multiple power transmitters 150 may be positioned to interact with a power receiver 152 on the transfer chamber robot 112. The power receiver 152 may be disposed on the robot end effector or on the distal robot arm or other member of the transfer chamber robot 112.

In some embodiments, power is transferred from a power transmitter 150 to the power receiver 152 when the transfer chamber robot 112 performs a substrate hand-off operation. For example, to retrieve a substrate from a processing chamber 107, the transfer chamber robot 112 inserts an end effector into the processing chamber 107. The power receiver 152 may become aligned with the power transmitter 150 associated with the particular processing chamber 107 so that the power transmitter 150 and the power receiver 152 may interact with one another. The power transmitter 150 may be energized and may transmit power to the power receiver 152. The power receiver 152 may receive the transmitted power. The received power may be provided to a power storage device on the transfer chamber robot 112. After retrieving the substrate, the transfer chamber robot 112 may actuate the robot arms to transport the substrate to another processing chamber 107 or to one of the degassing chambers 104. During the robot movements between substrate hand-off locations, the electrical load(s) at the end effector may continue to be powered or actuated by the electrical energy stored in the power storage device. The transfer chamber robot 112 may insert the end effector carrying the substrate into the chamber. The power receiver 152 may become aligned with another power transmitter 150 associated with the chamber so that the power transmitter 150 can transmit power to the power receiver 152. The transfer chamber robot 112 may continue operating to transport substrates as normal, and the power receiver 152 may receive power transmitted from any one of the power transmitters 150 disposed proximate an associated substrate transport path when the power receiver 152 becomes aligned, such as during substrate hand-offs, etc. This method or process of periodic charging during normal robot operation movements and sequences allows end effector electrical loads to be powered and/or actuated indefinitely without need to pause the robot movements to allow charging or for battery replacements, etc.

In some embodiments, system 100 includes a levitation mover, such as a magnetic levitation mover. The magnetic levitation mover may take the place and/or perform the function of transfer chamber robot 112 in some embodiments. In some embodiments, the levitation mover can move about the interior of the transfer chamber 106 or the FI 101 to transport substrates. One or more magnetic levitation tracks may be disposed across the transfer chamber 106 and/or the FI 101 to facilitate movement of the levitation mover about the chamber.

The levitation mover may include a substrate-handling robot mounted on a levitation mover base. The substrate-handling robot may include one or more robot arms and one or more end effectors for handling and/or transporting substrates. In some embodiments, each of the end effectors includes an electrical load, such as an electrostatic chuck, a heater, and/or one or more sensors, etc. In some embodiments, the electrical load is powered using a power storage device disposed on a robot arm and/or end effector. The power storage device may be charged and/or re-charged using a power transmitter-receiver pair. For example, and in some embodiments, the robot on the levitation mover includes power receivers 152 proximate the end effectors. During a substrate hand-off event (e.g., at a substrate hand-off location), a power receiver may substantially align with a power transmitter 150 so that power can be transferred from the power transmitter to the power receiver 152. Electricity from the power receiver 152 may be stored in the power storage device for powering the electrical load on the end effector, such as during a substrate transport event.

A controller 109 controls various aspects of the manufacturing system 100. The controller 109 is and/or includes a computing device such as a personal computer, a server computer, a programmable logic controller (PLC), a microcontroller, and so on. The controller 109 includes one or more processing devices, which, in some embodiments, are general-purpose processing devices such as a microprocessor, central processing unit, or the like. More particularly, in some embodiments, the processing device is a complex instruction set computing (CISC) microprocessor, reduced instruction set computing (RISC) microprocessor, very long instruction word (VLIW) microprocessor, or a processor implementing other instruction sets or processors implementing a combination of instruction sets. In some embodiments, the processing device is one or more special-purpose processing devices such as an application specific integrated circuit (ASIC), a field programmable gate array (FPGA), a digital signal processor (DSP), network processor, or the like. In some embodiments, the controller 109 includes a data storage device (e.g., one or more disk drives and/or solid state drives), a main memory, a static memory, a network interface, and/or other components. In some embodiments, the controller 109 executes instructions to perform any one or more of the methods or processes described herein. The instructions are stored on a computer readable storage medium, which include one or more of the main memory, static memory, secondary storage and/or processing device (during execution of the instructions). The controller 109 receives signals from and sends controls to factory interface robot 111 and wafer transfer chamber robot 112 in some embodiments.

According to one aspect of the disclosure, to transfer content 110 (e.g., a substrate) into a processing chamber 107, the content 110 is removed from an enclosure system 130B via factory interface robot 111 located in FI 101. The factory interface robot 111 may transfer the content 110 through one of the first vacuum ports 103a, 103b and into a respective degassing chamber 104a, 104b. The transfer chamber robot 112 located in the transfer chamber 106 removes the content 110 from one of the degassing chambers 104a, 104b through a second vacuum port 105a or 105b. The transfer chamber robot 112 moves the content 110 into the transfer chamber 106, where the content 110 is transferred to a processing chamber 107 through a respective port 108. After processing, the processed content 110 (e.g., a substrate supported on a substrate support and/or susceptor, etc.) is removed from the manufacturing system 100 in reverse of any manner described herein.

The manufacturing system 100 includes chambers, such as FI 101 (e.g., equipment front end module, EFEM) and adjacent chambers (e.g., load port 128x, enclosure system 130x, SSP, degassing chamber 104 (such as a loadlock chamber), or the like) that are adjacent to FI 101. Some or all of the chambers can be sealed. In some embodiments, inert gas (e.g., one or more of nitrogen, argon, neon, helium, krypton, or xenon) is provided into one or more of the chambers (e.g., FI 101 and/or adjacent chambers) to provide one or more inert environments. In some examples, FI 101 is an inert EFEM that maintains the inert environment (e.g., inert EFEM minienvironment) within FI 101 so that users do not need to enter FI 101 (e.g., the manufacturing system 100 is configured for no manual access within FI 101).

In some embodiments, gas flow (e.g., inert gas, nitrogen) is provided into one or more chambers (e.g., FI 101) of the manufacturing system 100. In some embodiments, the gas flow is greater than leakage through the one or more chambers to maintain a positive pressure within the one or more chambers. In some embodiments, the inert gas within FI 101 is recirculated. In some embodiments, a portion of the inert gas is exhausted. In some embodiments, the gas flow of non-recirculated gas into FI 101 is greater than the exhausted gas flow and the gas leakage to maintain a positive pressure of inert gas within FI 101. In some embodiments, FI 101 is coupled to one or more valves and/or pumps to provide the gas flow into and out of FI 101. A processing device (e.g., of controller 109) controls the gas flow into and out of FI 101. In some embodiments, the processing device receives sensor data from one or more sensors (e.g., oxygen sensor, moisture sensor, motion sensor, door actuation sensor, temperature sensor, pressure sensor, etc.) and determines, based on the sensor data, the flow rate of inert gas flowing into and/or out of FI 101.

The enclosure system 130x seals to the load port 128x responsive to being docked on the load port 128x. The enclosure system 130x provides purge port access so that the interior of the enclosure system 130x can be purged prior to opening the enclosure system 130x to minimize disturbance of the inert environment within FI 101.

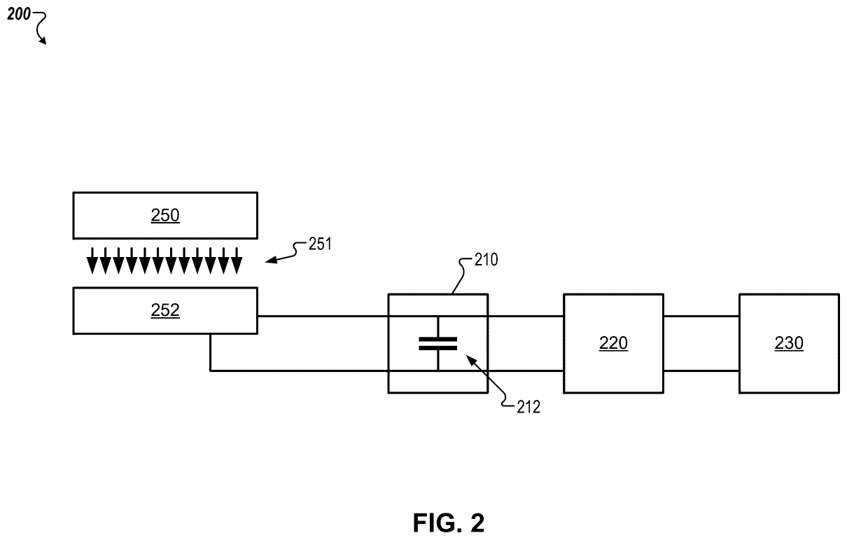

FIG. 2 illustrates an example schematic view of an electronic circuit 200, in accordance with some embodiments of the present disclosure. In some embodiments, the electronic circuit is disposed at least partially on an end effector of a substrate-handling robot (e.g., transfer chamber robot 112 of FIG. 1, etc.). At least a portion of the electronic circuit 200 may be implemented using a printed circuit board (PCB) attached to the substrate-handling robot. The electronic circuit 200 may be entirely or partially incorporated into the PCB.

The electronic circuit 200 includes an electrical load 230. The load 230 may be an electronic device, etc. In some embodiments the load 230 is an electrostatic chuck incorporated into an end effector of a substrate-handling robot. The electrostatic chuck may include one or more electrodes disposed within the end effector. The electrostatic chuck may be energized when the end effector is supporting a substrate for transport. The electrostatic chuck may generate an electrostatic force to secure the substrate to the end effector by electrostatic force. In some embodiments, the load 230 is a heater incorporated into an end effector. The heater may be energized to heat a substrate so that the thermal properties of the substrate are controlled. In some embodiments, the load 230 includes one or more sensors, such as capacitive sensors in the end effector that can detect the presence of a substrate and/or the bow or warpage of the substrate, etc. The sensors may include center-finding sensors used to determine the position of the substrate on the end effector. The sensors may include acceleration and/or vibrational sensors for measuring the acceleration and/or vibration of the end effector.

Electrical power for powering the electrical load 230 may be provided by a power storage device 210. In some embodiments, power storage device 210 includes one or more capacitors 212 (e.g., one or more super-capacitors, etc.) that can store electrical charge. The one or more capacitors 212 may be arranged in parallel or in series with one another, or a combination thereof. The power storage device may be proximate the robot end effector or may be disposed on and/or in the end effector itself. A power management module 220 provides electrical power from the power storage device 210 to the load 230. The power management module 220 may include a controller that controls the energizing of the load 230. For example, the module 220 may cause the load 230 (e.g., an electrostatic chuck) to be energized when a substrate is disposed on the end effector for transport. The module 220 may cause the load 230 to be de-energized when the substrate is handed off (e.g., placed, etc.). The power management module 220 may include a power management circuit to regulate the power supplied to the load 230. The power management circuit may provide a steady voltage to the electrical load 230. For example, and in some embodiments, the module 220 includes a voltage regulator to regulate the voltage of electricity received from the power storage device 210 and provided to the load 230. When the power storage device 210 holds a charge in excess of a threshold voltage (e.g., 5 volts, etc.), the module 220 may regulate the voltage supplied to the load 230 down to the threshold voltage. Similarly, when the power storage device 210 holds a charge less than the threshold voltage, the module 220 may regulate the voltage supplied to the load 230 up to the threshold voltage. The module 220 may include circuitry (e.g., including regulators, etc.) that boost the stored voltage to much higher voltages as needed to electrostatically chuck the substrate to the end effector, for example. The module 220 may include further circuity (e.g., including regulators, etc.) to provide decreased voltages for other circuits, etc.

The power storage device 210 may intermittently receive electrical power from a power receiver 252. In some embodiments, the power receiver 252 intermittently receives power from a power transmitter 250. When the robot end effector is positioned to hand-off a substrate (e.g., pick up a substrate, place a substrate, etc.) at a hand-off location, the power receiver 252 becomes substantially aligned with the power transmitter 250. The power transmitter 250 then transmits power 251 to the power receiver 252. In some embodiments, the power transmitter 250 is an inductive transmitter and the power receiver 252 is an inductive receiver, each with their own respective inductive coil. When the power receiver 252 is concentrically aligned with the power transmitter 250, power 251 may be supplied from the power transmitter 250 to the power receiver 252 by inductive power transfer. The inductive coil of the power transmitter 250 may be energized, creating an inductive field beneath the power transmitter 250. The inductive coil of the power receiver 252 may interact with the inductive field created by the power transmitter 250, causing electricity to be generated within the coil. Electricity may be provided from the power receiver 252 to the power storage device 210.

In some embodiments, the power transmitter 250 and the power receiver 252 transfer power by inductive charging. For example, the power transmitter 250 may include an inductive charging transmitter and the power receiver 252 may include an inductive charging receiver.

Electrical power may be inductively transmitted from the power transmitter 250 to the power receiver 252. Electricity from the power receiver 252 may be provided to the power storage device 210. In alternative embodiments, the power transmitter 250 and the power receiver 252 transfer power by solar charging. For example, the power transmitter 250 may be a light source and the power receiver 252 may be a solar receiver (e.g., such as a solar panel, etc.). The solar receiver may convert the solar energy (e.g., light energy, etc.) received from the power transmitter 250 into electricity. The electricity may be provided to the power storage device 210. In alternative embodiments, the power transmitter 250 and the power receiver 252 transfer power by optical charging. For example, the power transmitter 250 may be an optical source and the power receiver 252 may be an optical receiver. The optical receiver may convert the optical energy received from the power transmitter 250 into electricity. The electricity may be provided to the power storage device 210. In another alternative embodiment, the power transmitter 250 and the power receiver transfer power by RF charging. For example, the power transmitter 250 may be an RF transmitter and the power receiver 252 may be an RF receiver. The RF receiver may convert RF energy received from the power transmitter 250 into electricity, and the electricity provided to the power storage device 210.

In some embodiments, data can be transmitted between the power transmitter 250 and the power receiver 252. Transmitted data may include the charge state of the power storage device 210, and/or a condition of the electrical load 230. The data may be transmitted using a wireless connection between the power receiver 252 and the power transmitter 250. For example, data signals can be sent from the power receiver 252 to the power transmitter 250 (or vice versa) inductively during power transmission. The transmission of power from the power transmitter 250 to the power receiver 252 may be controlled based on data transmitted from the power receiver 252 to the power transmitter 250.

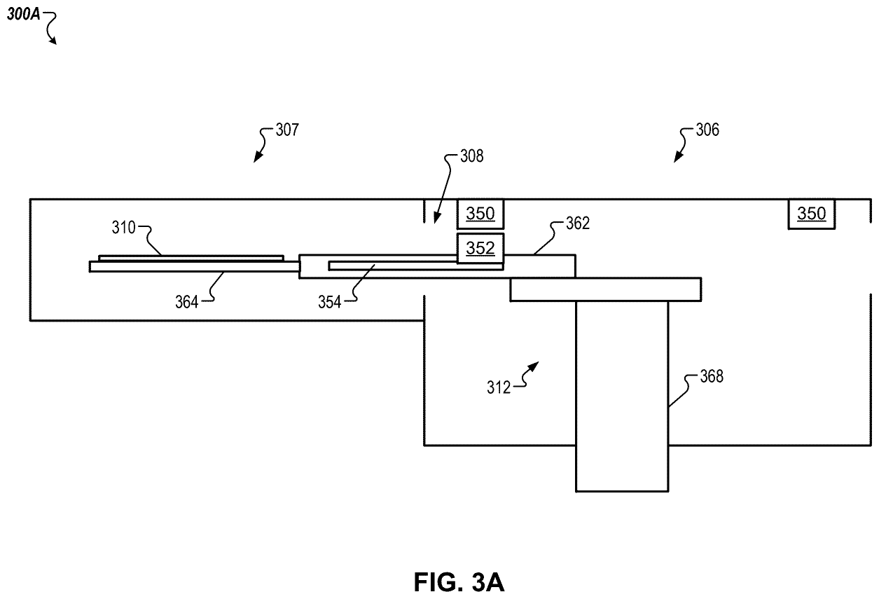

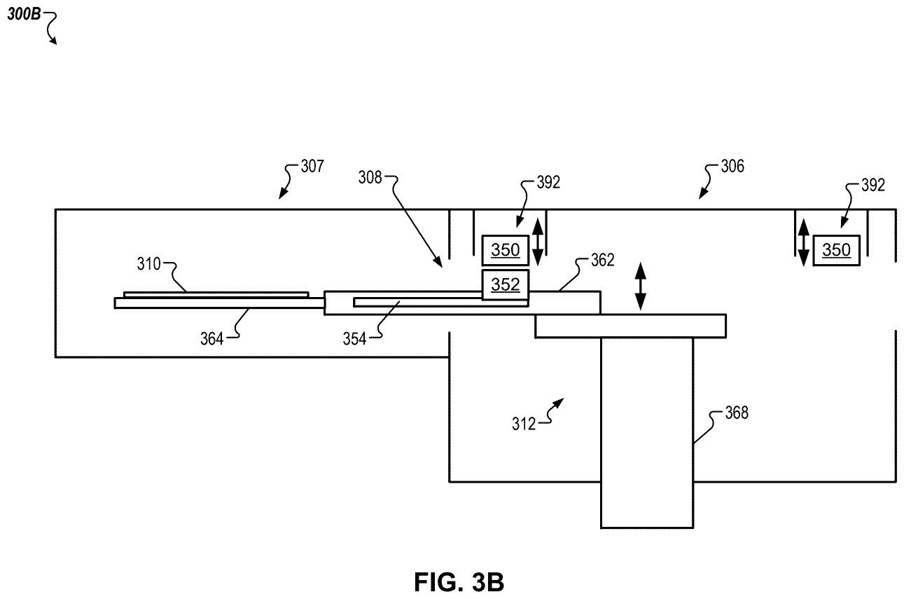

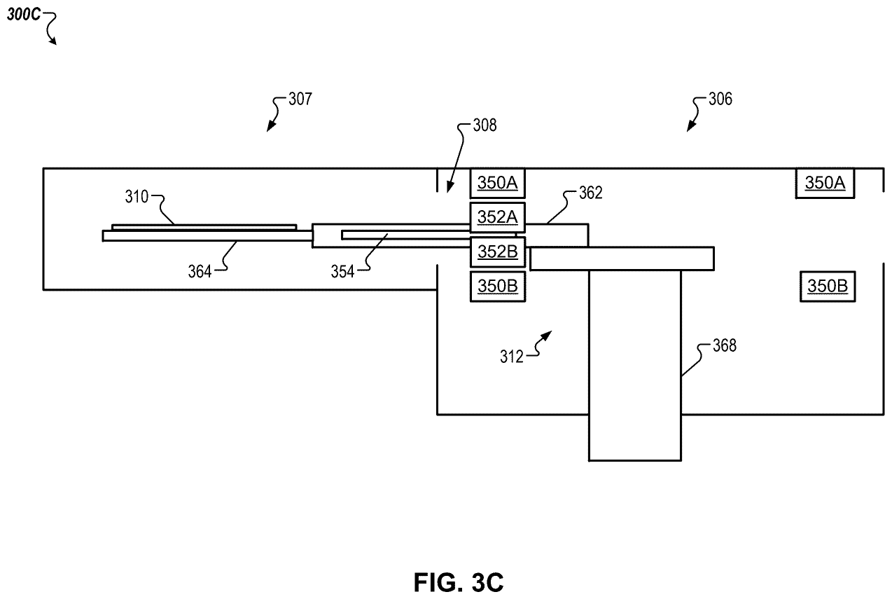

FIGS. 3A-C illustrate simplified side views of systems utilizing wireless charging for a robot end effector, in accordance with some embodiments of the present disclosure. Referring to FIG. 3A, a system 300A is shown. In some embodiments, a substrate-handling robot 312 is disposed within a chamber, such as transfer chamber 306, for transporting substrates 310. The robot 312 may include a motor stack 368, a robot arm 362, and an end effector 364. The end effector 364 may be configured to support one or more substrates 310 for transport. In some embodiments, the end effector 364 includes an electrical load, such as a heater, one or more sensors, and/or an electrostatic chuck.

For transporting a substrate 310, the robot 312 may insert the end effector 364 into a chamber 307. The chamber 307 may be a processing chamber or a degassing chamber. The robot 312 may extend the end effector 364 and/or a robot arm 362 through a port 308 formed in a facet between the chamber 307 and the transfer chamber 306. While the end effector 364 is in the chamber 307, such as to pick up or place a substrate 310, a power receiver 352 may be aligned with a power transmitter 350. The power transmitter may be disposed proximate the facet separating the chamber 307 from the transfer chamber 306. In some embodiments, the power transmitter 350 is disposed above the robot arm 362 and above the power receiver 352. The power receiver 352 may be on a top side of the robot arm 362 or on a top side of the end effector 364. In some embodiments, the power transmitter 350 is disposed beneath the robot arm 362 and beneath the power receiver 352. The power receiver 352 may be on a bottom side of the robot arm 362 or on a bottom side of the end effector 364. In some embodiments, the power transmitter 350 is at a fixed height corresponding to the height of the robot arm 362 when the robot 312 is picking up or placing a substrate 310. Power may be transferred from the power transmitter 350 to the power receiver 352, such as by inductive power transfer, solar power transfer, optical power transfer, or RF power transfer, etc. Power received by the power receiver 352 may be stored in a power storage device of circuit 354. In some embodiments, circuit 354 includes a module for controlling the supply of electricity to the electrical load on the end effector 364.

To transport the substrate 310, the robot 312 may retract the end effector 364 from the chamber 307 and transfer the substrate 310 to another chamber or station. While transferring the substrate 310, the electrical load of the end effector 364 may be energized (e.g., by the control module of circuit 354). Electrical power from the power storage device may be provided to the electrical load. As described herein, the electrical load may be an electrostatic chuck (e.g., for electrostatically secure the substrate 310 to the end effector 364), a heater (e.g., for heating the substrate), or one or more sensors, etc. In some embodiments, while placing the substrate 310 at the new chamber or station, the power receiver 352 may be aligned with another power transmitter 350. Power may be transferred from another power transmitter 350 to the power receiver 352 to replenish in part or in full, the electrical power used by the electrical load during transfer of the substrate 310. Each individual charging event may or may not provide full replacement of lost (e.g., used) energy. In some instances, it may take several charging events to replace lost energy. The amount of power transferred during a charging event may be dependent upon the gap between the power transmitter 350 and the power receiver 352, dwell time for the robot end effector 364 (e.g., wait time for a substrate hand-off operation, etc.). Additionally, substrate transport events may use different amounts of stored energy. Several factors may include duration of the transport event or faults that occur during the event such as dirty wafers or arc discharges, etc.

Referring to FIG. 3B, a system 300B is shown. In some embodiments, the power transmitters 350 are vertically movable. The power transmitters 350 may move in a first vertical direction (e.g., up) and an opposite second vertical direction (e.g., down) commensurate with vertical motion of the robot 312. For some substrate hand-off operations (e.g., pickup up a substrate or placing a substrate, etc.), the end effector 364 is to move vertically. The robot 312 may actuate the end effector 364 vertically by moving the motor stack 368, and/or the robot arm 362 up or down. In some embodiments, the power transmitter 350 aligned with the power receiver 352 is caused to move up or down with the robot arm 362. An actuator may cause the power receiver 350 to move up or down within a channel 392 or along a rail, etc. The power transmitter 350 may be caused to move by an electromechanical actuator (e.g., a linear actuator), a spring actuator, and/or a magnetic actuator. In some embodiments, the power transmitter 350 is caused to move vertically such that a minimum threshold gap and/or a maximum threshold gap is maintained between the power transmitter 350 and the power receiver 352.

Referring to FIG. 3C, a system 300C is shown. In some embodiments, power is wirelessly provided to the circuit 354 by more than one power transmitter-receiver pair. In some embodiments, a top side power transmitter 350A wirelessly provides power to a top side power receiver 352A. At least one additional power transmitter may wirelessly provide power to at least one additional power receiver. In some embodiments, a bottom side power transmitter 350B wirelessly provides power to a bottom side power receiver 352B. One power transmitter-receiver pair may be on a first side of the robot arm 362 and an additional power transmitter receiver pair may be on an opposite side of the robot arm 362. In some embodiments, power transfer using two power transmitter-receiver pairs is twice as fast as using one pair, such as in systems 300A and 300B. In some embodiments, the robot 312 moves vertically. The gaps between the power transmitters 350 and the power receivers 352 may vary as the robot arm 362 moves up or down, however, the average gap between the power transmitters 350 and the power receivers 352 may remain the same such that the average power transfer remains substantially constant.

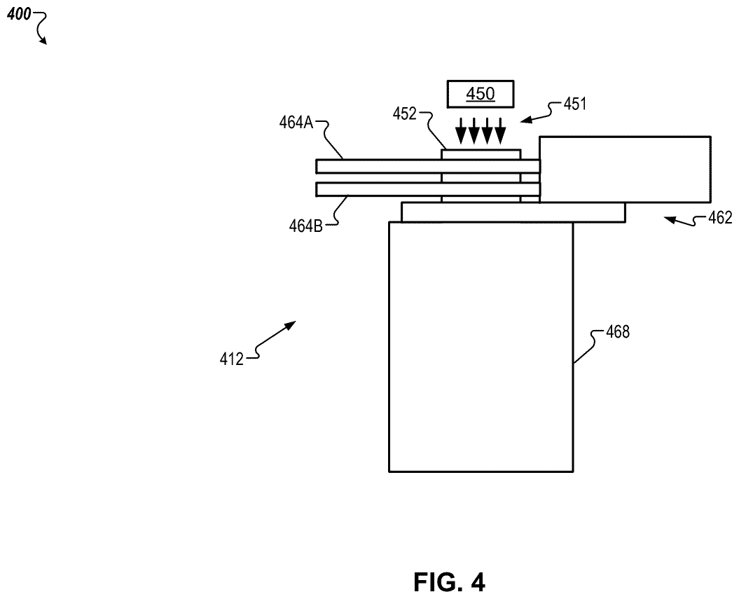

FIG. 4 illustrates a simplified side view of a system 400 utilizing wireless charging for a robot end effector, in accordance with some embodiments of the present disclosure. In some embodiments, a substrate-handling robot 412 includes multiple end effectors and multiple robot arms 462 powered by a motor stack 468. For example, a first end effector 464A may be coupled with a first distal robot arm 462 and a second end effector 464B may be coupled with a second distal robot arm 462. In some embodiments, each of the end effectors include an electrical load, such as an electrostatic chuck, a heater, and/or one or more sensors, etc. The end effectors 464 may transport substrates around a central axis of robot 412. In some embodiments, because the central axis of robot 412 does not move, a power transmitter-receiver pair may be disposed coaxial with the central axis of robot 412. In some embodiments, a power receiver 452 is disposed coaxial with the central axis of robot 412. A power transmitter 450 may be disposed above the power receiver 452. The power transmitter 450 and the power receiver 452 may be aligned to interact with one another. For example, power 451 can be transferred from the power transmitter 450 to the power receiver 452. The power transmitter-receiver pair may continuously transfer power for powering the electrical load(s) because the central axis of robot 412 does not move. For example, the power transmitter-receiver pair is disposed at the central axis of rotation of the robot 412 so may always be aligned for the transfer of power. The end effectors and robot arms may rotate about the central axis without interrupting the power transfer from the power transmitter 450 to the power receiver 450.

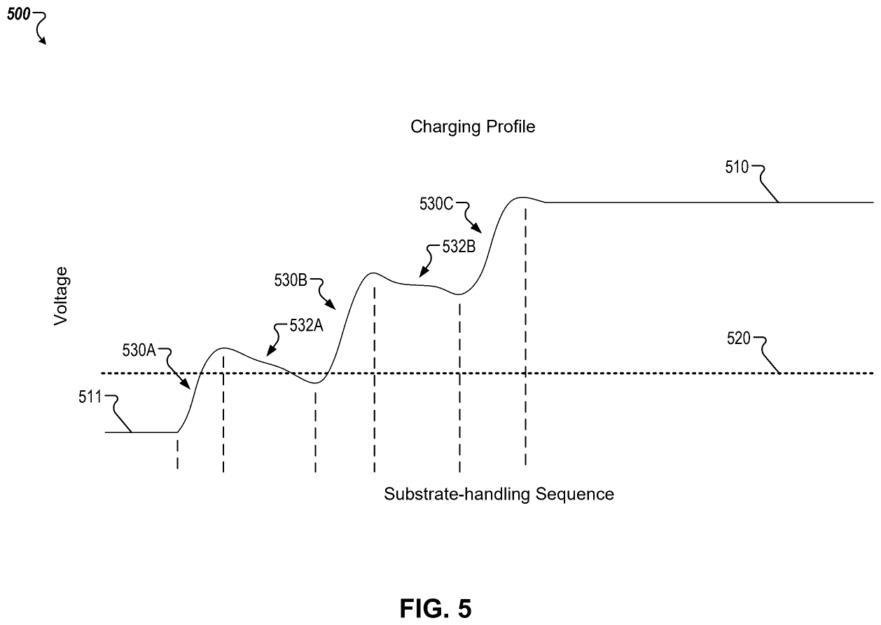

FIG. 5 illustrates a plot 500 of a charging profile 510 for wireless charging of a robot end effector, in accordance with some embodiments of the present disclosure. In some embodiments, the charging profile 510 is associated with the amount of charge stored in a power storage device, such as power storage device 210 of FIG. 2.

In some embodiments, the stored charge begins at an initial voltage 511. During a first charging event 530A, the voltage (e.g. energy stored in a capacitor) at the power storage device may increase. The first charging event 530A may take place while the robot performs a first substrate hand-off operation. In some embodiments, during the first charging event 530A, a power receiver (e.g., on a robot arm or on a robot end effector, etc.) may be substantially aligned with a power transmitter, allowing power to be transferred from the power transmitter to the power receiver. The robot may perform a substrate hand-off operation, such as picking up a substrate or placing a substrate, during each charging event. In some embodiments, the initial voltage level 511 is below a threshold voltage 520. When the charge level (e.g., voltage level) is below the threshold voltage 520, an electrical load on the robot end effector may not be adequately powered.

During a first transport event 532A, a substrate may be transported from a first substrate hand-off location to a second substrate hand-off location (e.g., from one processing chamber to another processing chamber, from a degassing chamber to a processing chamber, etc.). During the first transport event 532A, an electrical load on the robot end effector may be powered in part or in full and/or energy leakages may be present. For example, an electrostatic chuck may be energized to electrostatically secure the substrate to the end effector. In another example, a heater may be energized to heat the substrate. In a further example, one or more sensors on the end effector may be activated. In a further example, storage capacitor(s) may have some amount of inherent energy leakage. Additionally, loads such as control circuitry, voltage regulators, and other similar loads may have some residual power draw even when not turned ON or otherwise fully enabled, etc. Likewise, there may be a wireless communication system powered by the storage device so that the end effector control system can transmit and receive power status, threshold alarms, and receive control signals and other communication(s) and/or control signal(s) between the end effector loads and a control host.

Powering the electrical load may decrease the amount of stored charge (e.g., available voltage). If the stored charge causes voltage level to fall below the threshold voltage 520, the electrical load may not be adequately powered. Logical decisions (e.g., made by a controller or host system, etc.) regarding the movement of the robot and/or the energization of the electrical load on the end effector of the robot may be made based on the determined level of stored charge (e.g., the stored voltage, etc.) in the power storage device. If it is determined that the usable energy stored in the power storage device is insufficient, operation of the robot may be altered. An early warning control system associated with the power storage device may transmit an alert to a host based on the threshold voltage and/or other thresholds. The alert may be indicative of control signal(s) informing the robot host to slow down for example, in order to avoid possible substrate movement (e.g., sliding, displacement, etc.) on the end effector. In some embodiments, operation of the robot may be altered when the available voltage is determined to be below the threshold voltage 520. For example, and in some embodiments, an electrostatic chuck incorporated into a robot end effector may not produce an adequate electrostatic force to secure a substrate on the end effector when energized with a charge below the threshold voltage 520. Accordingly, the accelerations and/or decelerations of the end effector may be slowed when the stored charge is below the threshold voltage 520 so that the transported substrate does not slide or otherwise become dislodged on the end effector. In some embodiments, the threshold voltage 520 includes a lower threshold and an upper threshold to account for hysteresis. When the available voltage falls below the lower threshold, the operation of the robot may go into the altered mode (e.g., slower end effector accelerations, etc.). When the available voltage climbs above the upper threshold, the normal operation of the robot may resume.

During a second charging event 530B, the power storage device may be charged. The second charging event 530B may take place while the robot performs a second substrate hand-off operation. In some embodiments, the power receiver on the robot is aligned with a power transmitter during the second charging event 530B so that power can be transferred from the power transmitter to the power receiver. The power transmitter associated with the second charging event 530B may be different than the power transmitter associated with the first charging event 530A. In some embodiments, the charge stored in the power storage device may cause voltage to exceed the threshold voltage 520 during the second charging event 530B. Subsequent to the second charging event 530B, a second transport event 532B may occur. During the second transport event 532B, a substrate (e.g., the same substrate or a different substrate, etc.) may be transported from the second substrate hand-off location to a third substrate hand-off location. The electrical load may be energized during the second transport event 532B, decreasing the amount of stored voltage.

Subsquently, a third charging event 530C may occur and the power storage device may be charged. The third charging event 530C may take place while the robot performs a third substrate hand-off operation. In some embodiments, the power receiver on the robot is aligned with a power transmitter during the third charging event 530C so that power can be transferred from the power transmitter to the power receiver. The power transmitter associated with the third charging event 530C may be different than the power transmitters associated with either of the first or second charging events. Further transport events and/or charging events may subsequently occur during operation of the robot to transport substrates within a processing system.

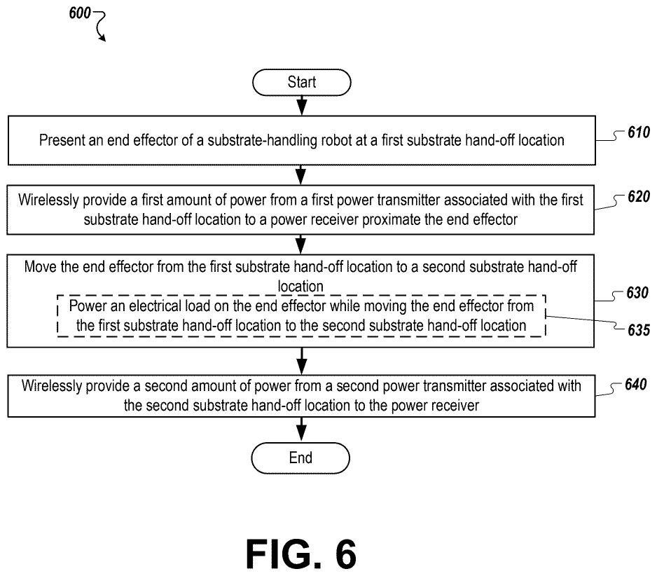

FIG. 6 is a flow diagram of a method 600 for wirelessly charging a robot end effector, in accordance with some embodiments of the present disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 610, an end effector of a substrate-handling robot is presented at a first substrate hand-off location. The first substrate hand-off location may be a processing chamber, a degassing chamber, a substrate support (e.g., a pedestal, etc.), or another type of station, etc. In some embodiments, the end effector is extended to pick up or place a substrate at the first hand-off location.

At block 620, a first amount of power is wirelessly provided from a first power transmitter associated with the first substrate hand-off location to a power receiver on the robot proximate the end effector. The first power transmitter may be disposed proximate the first substrate hand-off location. In some embodiments, the power receiver on the robot is substantially aligned with the first power transmitter when the end effector is presented at the first substrate hand-off location. The power receiver and the first power transmitter may be aligned so that power can be transferred from the transmitter to the receiver, such as by inductive power transfer, solar power transfer, optical power transfer, or RF power transfer.

At block 630, the end effector is moved from the first substrate hand-off location to a second substrate hand-off location. The second substrate hand-off location may be another processing chamber, degassing chamber, substrate support, etc. At block 635, while the end effector is moved from the first substrate hand-off location to the second substrate hand-off location, an electrical load on the end effector may be powered. In some embodiments, an electrostatic chuck on the end effector is energized to generate an electrostatic force to electrostatically secure the substrate to the end effector while moving from the first hand-off location to the second hand-off location.

At block 640, a second amount of power is wirelessly provided from a second power transmitter associated with the second substrate hand-off location to the power receiver. The second power transmitter may be disposed proximate the second substrate hand-off location. In some embodiments, the power receiver on the robot is substantially aligned with the second power transmitter when the end effector is at the second substrate hand-off location. The power receiver and the second power transmitter may be aligned so that power can be transferred from the transmitter to the receiver.

It should be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

The embodiments of methods, hardware, software, firmware or code set forth above may be implemented via instructions or code stored on a machine-accessible, machine readable, computer accessible, or computer readable medium which are executable by a processing element. “Memory” includes any mechanism that provides (i.e., stores and/or transmits) information in a form readable by a machine, such as a computer or electronic system. For example, “memory” includes random-access memory (RAM), such as static RAM (SRAM) or dynamic RAM (DRAM); ROM; magnetic or optical storage medium; flash memory devices; electrical storage devices; optical storage devices; acoustical storage devices, and any type of tangible machine-readable medium suitable for storing or transmitting electronic instructions or information in a form readable by a machine (e.g., a computer).

Reference throughout this specification to “one embodiment” or “an embodiment” means that a particular feature, structure, or characteristic described in connection with the embodiment is included in at least one embodiment of the disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment, embodiment, and/or other exemplary language does not necessarily refer to the same embodiment or the same example, but may refer to different and distinct embodiments, as well as potentially the same embodiment.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such. Also, the terms “first,” “second,” “third,” “fourth,” etc. as used herein are meant as labels to distinguish among different elements and may not necessarily have an ordinal meaning according to their numerical designation.

What is claimed is:

1. A substrate processing system, comprising:
a transfer chamber;
at least one process chamber coupled with the transfer chamber;
a substrate-handling robot disposed within the transfer chamber, wherein the substrate-handling robot comprises a power receiver located proximate an end effector of the substrate-handling robot for handling a substrate; and
at least one power transmitter disposed proximate a facet between the transfer chamber and the at least one process chamber, wherein the power transmitter is configured to wirelessly transmit power to the power receiver when the power receiver is substantially aligned with the power transmitter.

2. The substrate processing system of claim 1, wherein the power transmitter comprises an inductive charging transmitter, wherein the power receiver comprises an inductive charging receiver, and wherein power is to be inductively transmitted from the inductive charging transmitter to the inductive charging receiver.

3. The substrate processing system of claim 1, wherein the substrate-handling robot further comprises a power storage device proximate the end effector, and wherein power received by the power receiver is stored in the power storage device.

4. The substrate processing system of claim 3, wherein the power storage device comprises a capacitor.

5. The substrate processing system of claim 1, wherein the substrate-handling robot further comprises an electrical load comprising one or more of:
one or more electrodes disposed within the end effector and configured to secure the substrate by an electrostatic force;
a heater configured to heat the substrate; or
one or more sensors.

6. The substrate processing system of claim 5, wherein the substrate-handling robot further comprises a power management circuit configured to provide a steady voltage to the electrical load.

7. The substrate processing system of claim 1, wherein when the end effector is disposed within the at least one process chamber, the power receiver is substantially aligned with the power transmitter.

8. The substrate processing system of claim 1, wherein the power transmitter is configured to move in a first vertical direction and an opposite second vertical direction with the end effector.

9. The substrate processing system of claim 1, further comprising:
a plurality of power transmitters, wherein each power transmitter of the plurality of power transmitters is associated with a corresponding substrate hand-off location.

10. The substrate processing system of claim 1, further comprising:
at least one additional power transmitter disposed proximate the facet, wherein the at least one power transmitter is disposed on a first side of the end effector and the at least one additional power transmitter is disposed on a second opposite side of the end effector.

11. The substrate processing system of claim 1, wherein the power transmitter and the power receiver are configured to transmit data between one another.

12. A system, comprising:
a substrate-handling robot disposed within a transfer chamber, wherein the substrate-handling robot comprises one or more robot arms and one or more substrate-handling end effectors; and
a power charging system configured to wirelessly provide electrical power to an electrical load on the one or more substrate-handling end effectors, wherein the power charging system comprises a transmitter and a receiver, and wherein the receiver is disposed on the substrate-handling robot.

13. The system of claim 12, wherein the transmitter comprises an inductive charging transmitter, wherein the receiver comprises an inductive charging receiver, and wherein power is to be inductively transmitted from the inductive charging transmitter to the inductive charging receiver.

14. The system of claim 12, wherein the substrate-handling robot further comprises a power storage device proximate the end effector, and wherein power received by the power receiver is stored in the power storage device.

15. The system of claim 12, wherein the electrical load comprises one or more of:
one or more electrodes disposed within the end effector and configured to secure the substrate by an electrostatic force;
a heater configured to heat the substrate; or one or more sensors.

16. A robot, comprising:
one or more robot arms; and
an end effector coupled with a robot arm of the one or more robot arms and configured to handle a substrate, wherein the end effector comprises an electrical load; and
a power receiver disposed on the robot arm or on the end effector, wherein the power receiver is configured to wirelessly receive power from a power transmitter when the power receiver is substantially aligned with the power transmitter, and wherein the electrical load is to be powered using the received power.

17. The robot of claim 16, wherein the power transmitter comprises an inductive charging transmitter, wherein the power receiver comprises an inductive charging receiver, and wherein power is to be inductively transmitted from the inductive charging transmitter to the inductive charging receiver.

18. The robot of claim 16, further comprising:
a power storage device proximate the end effector, wherein power received by the power receiver is to be stored in the power storage device.

19. The robot of claim 16, wherein the electrical load comprises one or more of:
one or more electrodes disposed within the end effector and configured to secure the substrate by an electrostatic force;
a heater configured to heat the substrate; or
one or more sensors.

20. An electronics processing system, comprising:
one or more chambers;
a substrate-handling robot disposed in a chamber of the one or more chambers; and
a power transmitter disposed proximate to a transfer path of the substrate-handling robot and configured to wirelessly provide power to a power receiver of the substrate-handling robot when the power receiver is substantially aligned with the power transmitter.

21. The electronics processing system of claim 20, wherein the power transmitter comprises an inductive charging transmitter, wherein the power receiver comprises an inductive charging receiver, and wherein power is to be inductively transmitted from the inductive charging transmitter to the inductive charging receiver.

22. The electronics processing system of claim 20, further comprising:
a plurality of power transmitters, wherein each power transmitter of the plurality of power transmitters is disposed proximate an associated substrate transport path.
